(19) United States
(12) Patent Application Publication
(10) Pub. No.: US 2005/0022860 A1
(43) Pub. Date: Feb. 3, 2005

(54) Thin-film photovoltaic module

(75) Inventor: Peng Seng Toh, Singapore (SG)

Correspondence Address: CONLEY ROSE, P.C., P. O. BOX 3267, HOUSTON, TX, 77253-3267, US

(73) Assignee: GRENIDEA ECODESIGN PTE LTD, Singapore (SG)

(21) Appl. No.: 10/903,615

(22) Filed: Jul. 30, 2004

(30) Foreign Application Priority Data
Aug. 1, 2003 (WO) PCT/SG03/00187

(51) Int. Cl. H01L 25/00

(52) U.S. Cl. 136/251; 438/64

(57) ABSTRACT

An improved thin-film photovoltaic module and a method for making the same are disclosed. The photovoltaic module comprises a plurality of photovoltaic cells disposed on a substrate having a plurality of substantially hemispheric protrusions on the surface thereof. The photovoltaic module is formed by first providing the substrate with the plurality of substantially hemispheric protrusions. A conducting material is then applied on the substrate to form a first conducting layer. Active ingredients, semiconductor layers or the like photovoltaic materials are subsequently deposited on the second conducting layer. Finally, a transparent conducting material is applied on the photovoltaic layer to form a second conducting layer.

### CROSS-REFERENCE TO RELATED APPLICATIONS

This application claims priority to and is a continuation of PCT Application No. PCT/SG03/00187, filed on Aug. 1, 2003, entitled “AN IMPROVED THIN-FILM PHOTOVOLTAIC MODULE,” and incorporated herein by reference.

### FIELD OF INVENTION

The present invention relates generally to a photovoltaic module. Specifically, the present invention relates to an improved thin-film photovoltaic module and a method for making the same.

### BACKGROUND

Photovoltaic cells, also typically known as solar cells, are generally structurally planar. A group of photovoltaic cells electrically connected and packaged in a single frame is referred to as a photovoltaic module. The photovoltaic cells use active ingredients for absorbing and converting light into electrical energy. The active ingredients are conventionally built on flat substrates.

Planar solar cells are most effective when light rays received are direct and perpendicular to the surface of the solar cells. When there is no direct solar radiation, for example, on a cloudy day, these solar cells are highly inefficient. Scattered light rays strike on the flat surface solar cells at different incident angles. When rays of light are directed at the surface of the solar cell at a high incident angle, the effective absorption area is reduced according to the cosine law. Furthermore, much of the light's energy is reflected away and thus wasted.

One existing approach to improve the utilization of the solar cells is the use of solar trackers to track the relative position of the sun. The solar tracker constantly aligns the solar cell with the position of the sun to ensure that sun rays are received by the solar cell perpendicular to the surface thereof. However, the solar tracker becomes ineffective when there is no direct sunlight available to the solar cell.

Another approach is to form the solar cells in the shape of a sphere. The sphere shape solar cells are capable of absorbing solar radiation from a wide range of incident angles. Further, sunrays reflected from one neighboring sphere shape solar cell may be absorbed by another neighboring sphere shape solar cell. This approach is disclosed in issued patents including U.S. Pat. Nos. 5,466,301, 5,278,097, and 5,457,057. The challenge of this approach is in the forming of the sphere shape solar cells each having a P-type interior and an N-type exterior or layer. Various processes for making the sphere shape solar cells are also disclosed in issued patents including U.S. Pat. Nos. 5,614,020 and 5,431,127.

The sphere shape solar cells disclosed provide a substantially better energy conversion efficiency; however, the sphere shape solar cell fabrication process is complex and can be costly.

Therefore, this is clearly a need for a simplified method of making a photovoltaic module without the foregoing disadvantages of conventional photovoltaic module making process.

### SUMMARY

An improved thin-film photovoltaic module and a method for making the same are disclosed. The photovoltaic module comprises a plurality of photovoltaic cells disposed on a substrate having a plurality of substantially hemispheric protrusions on the surface thereof. The photovoltaic module is formed by first providing the substrate with the plurality of protrusions. Photovoltaic layers are then formed over the substrate with the photovoltaic layers inheriting the profile of the protrusions to form photovoltaic cells. The photovoltaic cells are thereby shaped for efficient and effective sunlight absorption thereby.

In accordance with a first aspect of the invention, there is disclosed a method for forming a photovoltaic module, comprising the steps of:
providing a substrate having a mating surface, the substrate having a plurality of protrusions formed thereon, each of the plurality of protrusions having a profile; and
forming a photovoltaic cell over the mating surface of the substrate, the photovoltaic cell having outwardly opposing first face and second face, the photovoltaic cell being formed on the mating surface of the substrate with the first face of the photovoltaic cell interfacing at least a portion of the mating surface of the substrate,
wherein the photovoltaic cell conforms to the profile of the protrusions to impart the profile thereof to and thereby form protrusions on the second face of the photovoltaic cell, the protrusions on the second face of the photovoltaic cell physically inheriting the profile of the protrusions on the surface of the substrate.

In accordance with a second aspect of the invention, there is disclosed a photovoltaic module comprising:
a substrate having a mating surface, the substrate having a plurality of protrusions formed on the substrate, each of the plurality of protrusions having a profile; and
a photovoltaic cell having outwardly opposing first face and second face, the photovoltaic cell being formed on the mating surface of the substrate with the first face of the photovoltaic cell interfacing at least a portion of the mating surface of the substrate, the photovoltaic cell conforming to the profile of the protrusions to impart the profile thereof to and thereby form protrusions on the second face of the photovoltaic cell, the protrusions on the second face of the photovoltaic cell physically inheriting the profile of the protrusions on the surface of the substrate.

### BRIEF DESCRIPTION OF THE DRAWINGS

Embodiments of the invention are described hereinafter with reference to the following drawings, in which:

FIG. 1 shows a process flow diagram for forming a photovoltaic module according to an embodiment of the invention;

FIG. 2 shows a cross-sectional top view of a photovoltaic module according to an embodiment of the invention;

FIG. 3 shows a partial cross-sectional view of view A-A of FIG. 2;

FIG. 4 shows a perspective view of the photovoltaic module of FIG. 2; and

FIG. 5 shows a partial perspective view of view O of the photovoltaic module of FIG. 4.

### DETAILED DESCRIPTION

A method for forming a photovoltaic module for addressing the foregoing problems is described hereinafter.

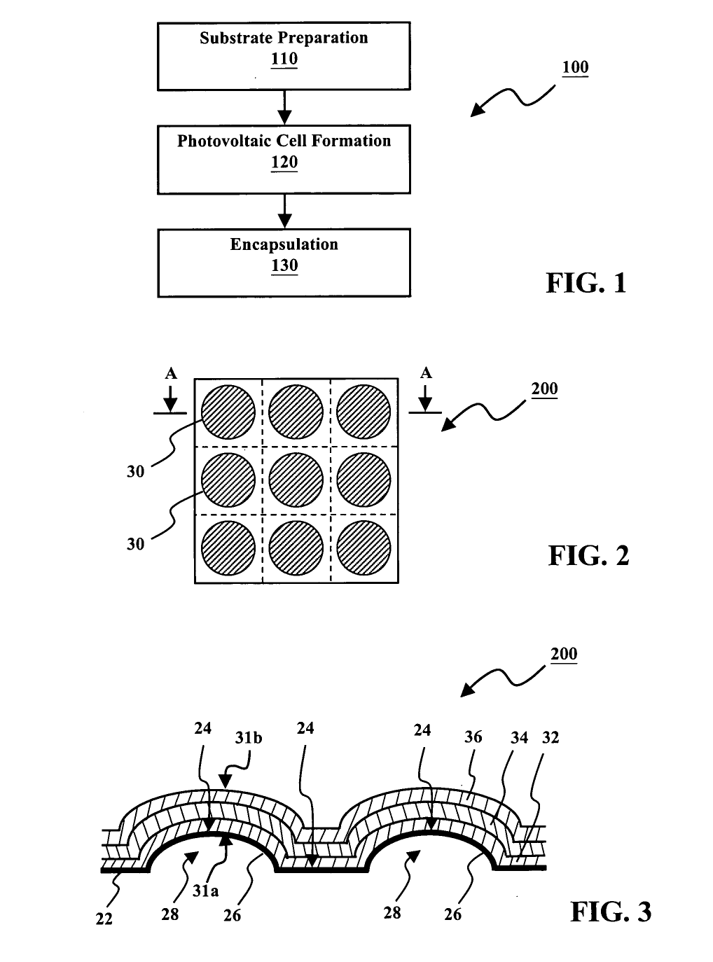

An embodiment of the invention, a photovoltaic module formation method 100 is described with reference to FIG. 1, which shows a process flow diagram thereof. The photovoltaic module formation method 100 is for forming a photovoltaic module 200 described with reference to FIGS. 2 and 3.

In a step 110 of the photovoltaic module formation method 100, a substrate 22 having a mating surface 24 on one side is provided. The substrate 22 has a plurality of protrusions 26 formed on the side thereof having the mating surface 24. The protrusions 26 are preferably spaced apart along the substrate 22 and arranged in a grid. Preferably, each protrusion 26 is shaped larger than one-third the span of a sphere, but not exceeding half the span of a sphere, for example a hemisphere. For example, each of the protrusions 26 has a profile 28 that is substantially hemispherical with a diameter within a range of 0.5 millimetre to 10 millimetres. The protrusions 26 provide a larger surface area of exposure to sunlight compare to the conventional flat circular surface area. Further, the substantially hemispherical shape of the protrusions 26 is substantially more effective in receiving sunlight from different angles and the neighbouring protrusions 26 increase mutual reflection and absorption of sunlight. Thus, more sunlight is received and converted into electricity instead of being reflected off the surface.

The substrate 22 is typically one of a metal substrate and a plastic substrate. For the metal substrate, a planar metallic sheet is preferably embossed and pressed to form the protrusions 26 thereon. For the plastic substrate, a molding machine, for example an injection-molding machine, is preferably used for molding the protrusions 26 on the plastic substrate.

Following the step 110 of providing the substrate 22, a plurality of photovoltaic cells 30 are formed on the mating surface 24 of the substrate 22 over the protrusions 26 in a step 120. The photovoltaic cells 30 constitute portions of a photovoltaic layer with a first face 31a and a second face 31b. Both the first face 31a and the second face 31b are outwardly opposing such that when the photovoltaic layer is formed with the first surface interfacing the mating surface 24 of the substrate 22, the second face 31b of the photovoltaic layer inherits the profile 28 of the plurality of protrusions 26 to form the photovoltaic cells 30.

Each photovoltaic cell 30 comprises a first conducting layer 32, a semiconductor layer 34, and a second conducting layer 36. The first conducting layer 32 is typically made of metal, while the second conducting layer 36 is typically made of a transparent conducting oxide, such as tin oxide. The semiconductor layer 34 is made of thin-film photovoltaic materials such as amorphous silicon (a-Si), cadmium telluride (CdTe), copper indium (gallium) diselenide, or film crystalline silicon. These materials are developed as means for substantially reducing the cost of photovoltaic (PV) systems.

Each of these materials is a strong light absorber and only needs to be approximately one micron thick, so material cost is significantly reduced. Further, these materials are amenable to large area deposition on to the substrate 22 of approximately one square meter in dimensions. Thus, high volume manufacturing is possible, which further reduces production cost.

In the step 120, the photovoltaic cells 30 are formed by first applying a layer of metal on the mating surface of 24 of the substrate 22 to form the first conducting layer 32. A layer of photovoltaic material, preferably amorphous silicon, is then applied over the first conducting layer 32 to form the semiconductor layer 34. The semiconductor layer 34 comprises two layers of amorphous silicon in contact with each other.

One layer of amorphous silicon is doped with boron to form a P-type amorphous silicon and the other layer is doped with phosphorous to form an N-type amorphous silicon. When the two layers are in contact with each other, preferably stacked one on top of the other, an electric field is created for producing a voltage difference between the first and second conducting layers 32 and 36. When photons (light energy) fall on the semiconductor layer 34, electrons in the P-type layer flow to the N-type layer thereby generating electric current.

Finally, a layer of transparent conducting oxide is applied over the semiconductor layer 34 to form the second conducting layer 36. The application of the different layers of the photovoltaic cells 30 can be easily performed by using known thin-film deposition techniques such as sputtering and chemical vapor deposition and the like thin-film deposition techniques.

To build up a useful amount of voltage, the photovoltaic cells 30 are laser scribed (not shown) to enable the front and back of adjacent cells in the grid to be directly electrically interconnected in series with no further need for solder interconnection between the photovoltaic cells 30.

Once the photovoltaic cells 30 are formed, the substrate 22 and the photovoltaic cells 30 are encapsulated with a layer of protective coating in a step 130. The protective coating is one of glass, resin, and polymer material. The substrate 22 and the photovoltaic cells are encapsulated to form a photovoltaic package with an exposure surface for exposure to sunlight. The exposure surface has a plurality of protrusions inherited from the photovoltaic cells when the protective coating is applied thereon. Alternatively, the photovoltaic package is formed with a planar exposure surface wherein the photovoltaic cells and the spaces therebetween are flood-filled with the protective coating to obtain surface planarity of the exposure surface therefrom.

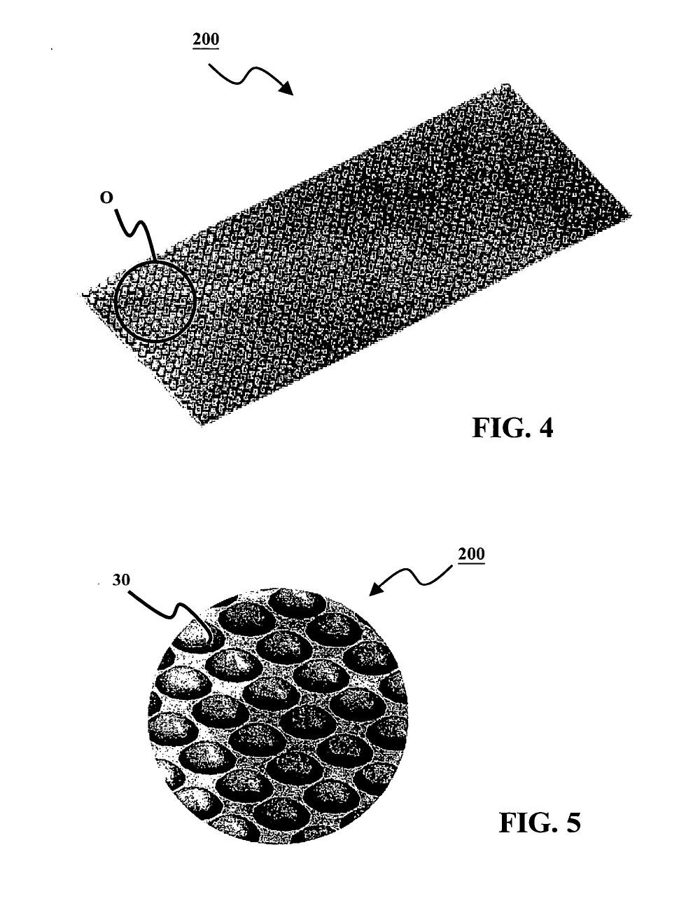

The steps 110, 120, and 130 of the photovoltaic module formation method 100 are implementable as an in-line manufacturing process to provide improved manufacturing efficiency and output. For example, the metal substrate 22 can be embossed and pressed to form the protrusions 26 before automatically being delivered by a line-based delivery system, for example a conveyor belt, to a downstream station for subsequently performing a step 120, where the photovoltaic cells 30 are formed and finally encapsulated in the step 130. A perspective view of the photovoltaic module 200 is shown in FIG. 4 with the photovoltaic cells being visually highlighted in FIG. 5.

In the foregoing manner, an improved thin-film photovoltaic module and a method for making the same are described according to an embodiment of the invention for addressing the foregoing disadvantages of conventional photovoltaic module. Although only one embodiment of the invention is disclosed, it will be apparent to one skilled in the art in view of this disclosure that numerous changes and/or modification can be made without departing from the scope and spirit of the invention.

1. A method for forming a photovoltaic module, comprising the steps of:
providing a substrate having a mating surface, the substrate having a plurality of protrusions formed thereon, each of the plurality of protrusions having a profile; and
forming a photovoltaic cell over the mating surface of the substrate, the photovoltaic cell having outwardly opposing first face and second face, the photovoltaic cell being formed on the mating surface of the substrate with the first face of the photovoltaic cell interfacing at least a portion of the mating surface of the substrate,
wherein the photovoltaic cell conforms to the profile of the protrusions to impart the profile thereof to and thereby form protrusions on the second face of the photovoltaic cell, the protrusions on the second face of the photovoltaic cell physically inheriting the profile of the protrusions on the surface of the substrate.

2. The method for forming a photovoltaic module as in claim 1, further comprising the steps of encapsulating at least a portion of the photovoltaic cell and the substrate in one of glass, resin and polymer material.

3. The method for forming a photovoltaic module as in claim 1, wherein the step of providing a substrate comprising the step of providing a substrate made of one of metal and plastic material.

4. The method for forming a photovoltaic module as in claim 1, wherein the step of providing a substrate comprising the step of molding the substrate to form the protrusions thereon.

5. The method for forming a photovoltaic module as in claim 1, the step of providing a substrate comprising the step of processing the provided substrate by one of embossing and pressing the substrate to form protrusions thereon.

6. The method for forming a photovoltaic module as in claim 1, the step of providing a substrate comprising the step of providing the substrate with the profile of each of the protrusions on the second face of the photovoltaic cell being substantially hemispherical.

7. The method for forming a photovoltaic module as in claim 6, the step of providing the substrate with the profile of each of the protrusions on the second face of the photovoltaic cell being substantially hemispherical comprising the step of providing the substantially hemispherical profile of each protrusion on the second face of the photovoltaic cell with a diameter within a range of 0.5 mm to 10 mm.

8. The method for forming a photovoltaic module as in claim 1, the step of providing a substrate comprising the step of providing the substrate with each of the protrusions on the second face of the photovoltaic cell with a shape exceeding one third the span of a sphere and not exceeding half the span of a sphere.

9. The method for forming a photovoltaic module as in claim 1, the step of forming a photovoltaic cell over the mating surface of the substrate comprising the steps of:
forming a first conducting layer over the mating surface of the substrate;
forming a semiconductor layer over the first conducting layer formed over the mating surface of the substrate; and
forming a second conducting layer over the semiconductor layer, the semiconductor layer being disposed between the first conducting layer and the second conducting layer,
wherein the first face and the second face of the photovoltaic cell constitutes a surface of the first conducting layer and a surface of the second conducting layer respectively.

10. The photovoltaic module as in claim 9, the step of forming a semiconductor layer comprising the step of forming a semiconductor layer comprising at least one pair of P-type and N-type semiconductor layers stacked one on top of the other.

11. The photovoltaic module as claim 1, wherein the step of providing a substrate comprising the step of providing the substrate with the plurality of protrusions being spaced apart along the mating surface of the substrate.

12. A photovoltaic module comprising:
a substrate having a mating surface, the substrate having a plurality of protrusions formed on the substrate, each of the plurality of protrusions having a profile; and
a photovoltaic cell having outwardly opposing first face and second face, the photovoltaic cell being formed on the mating surface of the substrate with the first face of the photovoltaic cell interfacing at least a portion of the mating surface of the substrate, the photovoltaic cell conforming to the profile of the protrusions to impart the profile thereof to and thereby form protrusions on the second face of the photovoltaic cell, the protrusions on the second face of the photovoltaic cell physically inheriting the profile of the protrusions on the surface of the substrate.

13. The photovoltaic module as in claim 12, wherein at least a portion of the photovoltaic cell and the substrate is encapsulated in one of glass, resin and polymer material.

14. The photovoltaic module as in claim 12, wherein the substrate is one of metal and plastic material.

15. The photovoltaic module as in claim 12, wherein the protrusions on the substrate are formed by molding.

16. The photovoltaic module as in claim 12, wherein the protrusions on the substrate are formed by one of embossing and pressing.

17. The photovoltaic module as in claim 12, wherein the profile of each of the protrusions on the second face of the photovoltaic cell is substantially hemispherical.

18. The photovoltaic module as in claim 17, wherein the substantially hemispherical profile of the protrusions of the photovoltaic cell has a diameter within a range of 0.5 mm to 10 mm.

19. The photovoltaic module as in claim 12, wherein each of the protrusions on the second face of the photovoltaic cell has a shape exceeding one third the span of a sphere and not exceeding half the span of a sphere.

20. The photovoltaic module as in claim 12, wherein the photovoltaic cell comprises of:
a first conducting layer;
a second conducting layer, the second conducting layer being substantially transparent; and
a semiconductor layer disposed between the first conducting layer and the second conducting layer,
wherein the first face and the second face of the photovoltaic cell constitutes a surface of the first conducting layer and a surface of the second conducting layer respectively.

21. The photovoltaic module as claim 20, wherein the semiconductor layer comprises of at least one pair of P-type and N-type semiconductor layers stacked one on top of the other.

22. The photovoltaic module as in claim 12, wherein the plurality of protrusions are spaced apart along the mating surface of the substrate.
